(19) United States
(12) Patent Application Publication
(10) Pub. No.: US 2004/0132260 A1
(43) Pub. Date: Jul. 8, 2004

(54) Process for fabricating a short-gate-length MOS transistor and integrated circuit comprising such a transistor

(75) Inventor: Damien Lenoble, Gieres (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics SA, Montrouge (FR)

(21) Appl. No.: 10/714,440

(22) Filed: Nov. 14, 2003

(30) Foreign Application Priority Data
Nov. 14, 2002 (FR) 0214255

(51) Int. Cl. H01L 21/336

(52) U.S. Cl. 438/306

(57) ABSTRACT

A process for fabricating an integrated circuit includes forming a gate on a crystalline silicon substrate, and amorphizing a region of the substrate to obtain an amorphous silicon region. Dopant is implanted in a subregion lying substantially within the amorphous silicon region of the substrate to form drain and source extensions. A source and drain are then formed at a low temperature.

### FIELD OF THE INVENTION

The present invention relates to integrated circuits, and especially but not exclusively, to isolated-gate field-effect transistors (MOSFET transistors) having a short gate length. The gate length of these transistors may be less than 180 nanometers, and in particular, may be less than about 100 nm.

### BACKGROUND OF THE INVENTION

The fabrication of MOS transistors having a small size, particularly those with nanometer dimensions and with a conventional architecture, is experiencing intrinsic problems that limit their operating characteristics. Among these problems, short channel effects (i.e., the lowering of the threshold voltage of the transistor as the gate length decreases and consequently as the channel length decreases) are becoming predominant. This has a negative impact on the current characteristics of the transistors.

These short channel effects are linked to a reduction in the effective length of the conduction channel because of the lateral diffusion (i.e., beneath the gate electrode) of the source and drain extension zones. The source and drain extension zones are commonly referred to by those skilled in the art as LDD zones.

One way of reducing these parasitic short channel effects is to reduce the depth of the junctions of these extension zones, thereby reducing the lateral diffusion (which is proportional to the vertical depth of the junction) of the extension zones. By reducing the depth of the extension zone junctions it is possible to control the lowering of the potential barrier between the source and drain when the drain is biased, an effect that is known as DIBL.

However, any reduction in the depth of the junction of these zones is accompanied by an increase in the layer resistance of these junctions when the depth becomes less than 40 nm in the case of standard fabrication processes that involve ion implantation of the dopant (typically boron and arsenic) followed by thermal activation by high temperature annealing. It should also be pointed out that depths of less than 30 nm are recommended for CMOS technologies below 100 nm. Furthermore, increasing the layer resistance of the junction increases the value of the parasitic resistance of the device, thus limiting the saturation current performance of the transistors.

Thus, manufacturers are confronted with a compromise between controlling the short-channel effects (i.e., controlling the threshold voltage to maintain the leakage current of the transistor below the desired values) and increasing the transistor performance characteristics (i.e., on-state saturation current) that are partly due to the value of the parasitic series resistance, and therefore to the junction resistance.

To improve the short-channel effects, it has been proposed to implant pockets of dopants in the channel region that extends from the drain region and from the source region. These pockets have the opposite type of conductivity to those of the source and drain extension regions from which they respectively extend.

In general, these pockets of dopants are implanted by an ion implantation technique after the gate has been produced and before the drain and source extension zones have been formed. During formation of these pockets, the dopants tend to disperse over the bare surface of the substrate. This considerably increases the level of doping in the junctions present at the drain/substrate and source/substrate interfaces. This increase in the level of doping results in a significant increase in the leakage currents and in the junction capacitance.

U.S. Pat. No. 6,008,098 discloses a process for fabricating shallow junctions using a layer of amorphous silicon. After amorphous silicon regions have been formed in the substrate around the gate, a dopant is implanted and then an annealing step is carried out at 800° C. for 40 seconds to activate the dopant that forms the source and drain extensions. Next, spacers are formed and then source and drain regions are formed. However, the latter step is carried out at high temperatures which is harmful to the source and drain extensions because of the risk of diffusion of the dopant.

### SUMMARY OF THE INVENTION

In view of the foregoing background, an object of the invention is to allow solid-phase epitaxy that is capable of forming small low-resistance source and drain extensions at a reasonable cost.

This and other objects, advantages and features in accordance with the invention are provided by a process for fabricating an integrated circuit comprising forming a gate on a substrate of crystalline silicon. The process may further include amorphization of one region of the substrate to obtain an amorphous silicon region, and implantation of a dopant in a subregion lying substantially within the region of the substrate to form drain and source extensions. Source and drain regions may then be formed at a low temperature.

Forming the sources and drains at a low temperature allows the dopants to be kept in place. Thus, harmful diffusion is avoided. In general, provisions may be made to prevent any increase to a high temperature after recrystallization of the amorphized region.

Spacers may be formed after the implantation. Formation of these spacers may be beneficial for activating the dopant and recrystallizing the amorphous silicon. The spacers may include silicon oxide and/or silicon nitride.

A low-temperature annealing step, for example between 650° C. and 800° C., may be carried out after the implantation. Preferably, the temperature to which the substrate is subjected remains below 800° C.

Advantageously, the step of forming the source and drain may include a deep amorphization substep to form an amorphized deep region. The deep amorphization may be carried out to a depth of 80 nm.

Forming the source and drain may also include a dopant implantation substep. The dopant implantation substep may take place before or after the deep amorphization. After the deep amorphization step or after the dopant species implantation substep, an amorphized silicon recrystallization substep is carried out. The silicon recrystallization substep may be common to the amorphous silicon region and to the deep amorphized region.

Advantageously, the formation of a silicide on the drain and source regions may include a low-temperature annealing substep. The annealing substep furthermore induces recrystallization of the deep amorphized region, and where appropriate, of the amorphous silicon region.

An annealing step may be carried out after formation of the spacers. Advantageously, doped pockets are formed in the substrate with a dopant having the opposite conductivity to that of the dopant of the implantation step.

The doped pockets may be formed before the amorphization step, or alternatively, they may be formed after the amorphization step. The doped pockets may also be formed before both the amorphization step and the dopant implantation step.

Spacers may be formed after the dopant implantation step. Spacers may also be formed before the amorphization step. The amorphization takes place to a depth of greater than 100 nanometers. A source and drain implantation step may be carried out after the amorphization. The source and drain formation step may include a low-temperature annealing step.

The amorphization step may include the implantation of electrically inactive heavy ions. The heavy ions are preferably chosen from silicon, germanium, argon, neon, zenon and krypton. The dopant implanted during the implantation step may be chosen from the following: B⁺, BF₂⁺, In⁺, As⁺, P⁺ and Sb⁺.

Preferably, the temperature of the source and drain formation step is below 800° C. However, the temperature of the source and drain formation step may be above 650° C.

Another aspect of the invention is directed to an integrated circuit comprising at least one transistor obtained by the above process. In one embodiment of the invention, the gate length of the transistor, measured parallel to the length of the channel, is less than 180 nanometers. The length of the channel may even be less than 100 nanometers.

The invention makes it possible to maintain the advantages of forming small source and drain extensions despite the subsequent fabrication steps. The following steps are carried out in a crystalline silicon substrate having a gate thereon. A region of the substrate is amorphized to obtain a first amorphous silicon region, dopants are implanted in a subregion lying substantially within the first region of the substrate to form drain and source extensions, and an annealing step is performed to activate the dopant by recrystallization. A second region of the substrate is amorphized to obtain a second amorphous silicon region, and the source and drain are formed at low temperature.

According to another embodiment of the process, the following steps may be carried out in a crystalline silicon substrate having a gate thereon. Dopants are implanted in the substrate to form doped pockets, and dopants having an opposite conductivity to that of the dopants of the pockets are implanted in a subregion lying substantially within the pockets to form drain and source extensions. Spacers are formed, and dopants are implanted in the substrate to form the drain and source. A region of the substrate is amorphized to obtain an amorphous silicon region comprising the subregion, and the amorphous region is recrystallized by low-temperature annealing. The drain and source will preferably be formed with the same dopants as the drain and source extensions.

According to another aspect of the invention, the following steps are carried out in a crystalline silicon substrate having a gate thereon. The crystal structure of a region of the substrate is altered to reduce the possibility of diffusion of dopants into the altered region. Dopants are implanted in a subregion essentially lying within the altered region for the purpose of forming drain and source extensions. The source and drain are formed at low temperature. The step of forming the source and drain may furthermore serve to activate the dopants of the subregion.

### BRIEF DESCRIPTION OF THE DRAWINGS

The present invention will be more clearly understood and other advantages will become apparent on reading the detailed description of a few methods of implementation given by way of non-limiting examples and illustrated by the appended drawings, in which:

FIGS. 1 to 8 are sectional views of a MOS transistor during its fabrication steps by a process according to the present invention; and

FIGS. 9 and 10 are sectional views of a MOS transistor during its fabrication steps by another process according to the present invention.

### DETAILED DESCRIPTION OF THE PREFERRED EMBODIMENTS

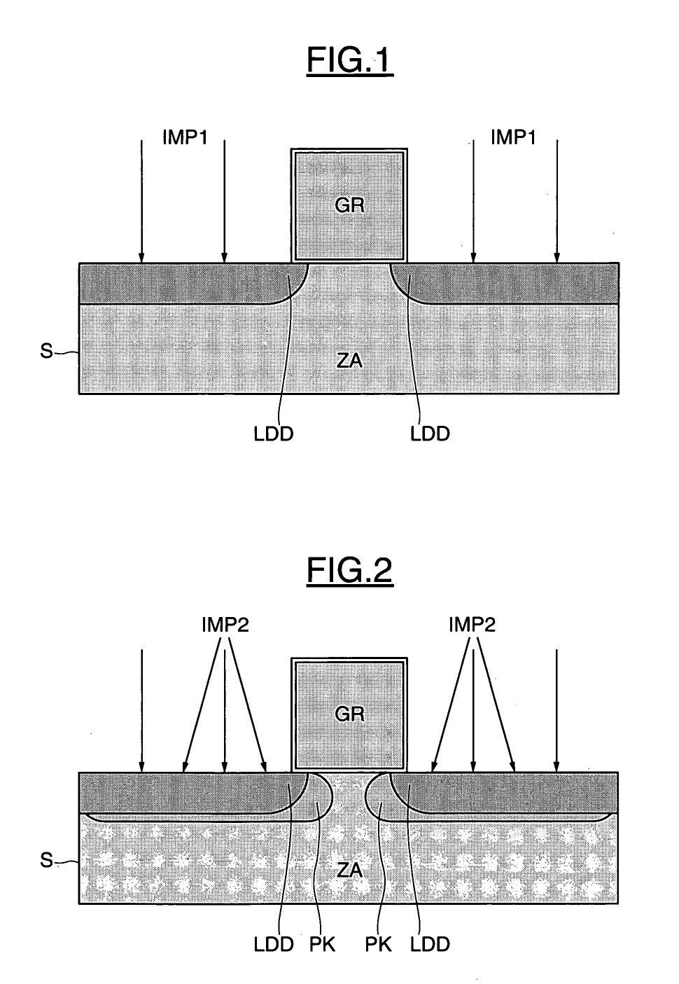

Referring initially to FIG. 1, a MOS transistor being fabricated includes a gate region GR formed on top of a substrate S and in an active zone ZA thereof, and may also be bounded by an isolating region that is not shown. The implantation IMP1 of dopants, for example boron, is carried out by ion or plasma implantation to form drain and source extensions LDD with a thickness of around 20 nm for example. More generally, the dopant will be chosen from the following ions: B⁺, BF₂⁺, In⁺, As⁺, P⁺ and Sb⁺. The extensions LDD extend slightly beneath the gate GR.

An optional step is to form pockets PK by oblique implantation IMP2 of dopants of the opposite type to that used for implanting the extensions LDD. These pockets PK may be implanted before or after the extensions LDD are implanted using an ion implantation technique, that is, by subjecting the substrate S to a flux of ions. These pockets are implanted near the extensions LDD while using the edges of the gate GR as an implantation mask.

These pockets PK contribute to improving the control of the short-channel effects, and in particular, to prevent too large a drop in the threshold voltage of the transistor. It is possible to carry out the implantation of the pockets PK with the same photolithographic masking level as that of the zones LDD while maintaining their effectiveness. This is because the effectiveness of these pockets is dependent on them being precisely localized in the active zone beneath the gate as readily understood by those skilled in the art. This localization is less dispersed when the implantation energy is low.

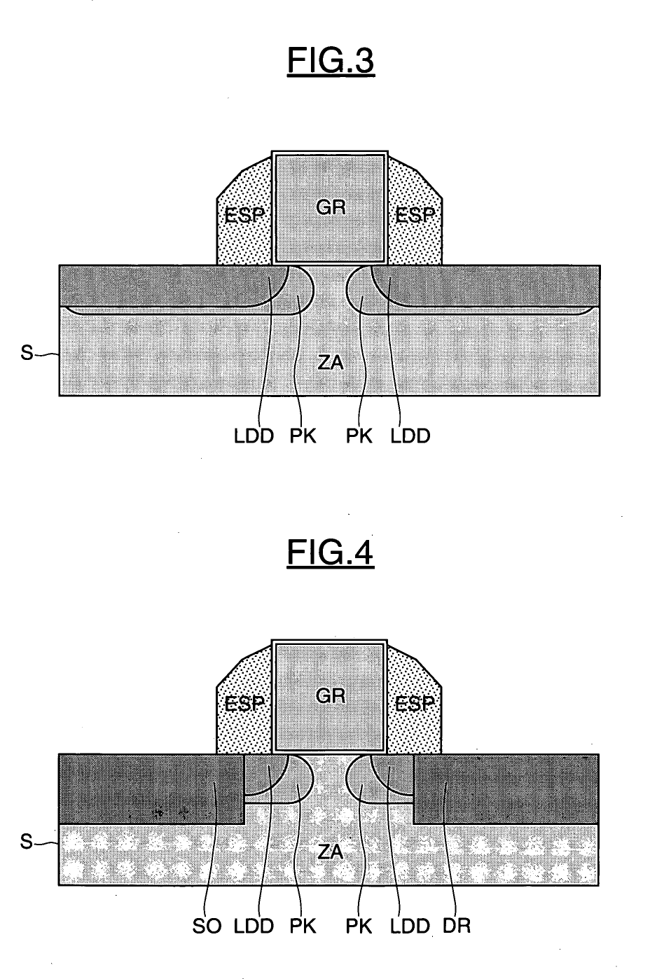

Next, spacers ESP are produced at a low temperature. The spacers ESP are placed along the sides of the gate GR and are made of silicon oxide by TEOS deposition for example, and by depositing silicon nitride followed by an etching step (FIG. 3). During annealing of the spacers ESP, the temperature remains below 800° C., and preferably at 700° C. so as not to cause diffusion of the dopants. The size of the spacers at the base may be between 20 and 80 nm.

As illustrated in FIG. 4, source SO and drain DR regions are formed by implanting dopants having the same conductivity as the extensions LDD. The source SO and drain DR regions are thicker than the extensions LDD and are thicker than the pockets PK.

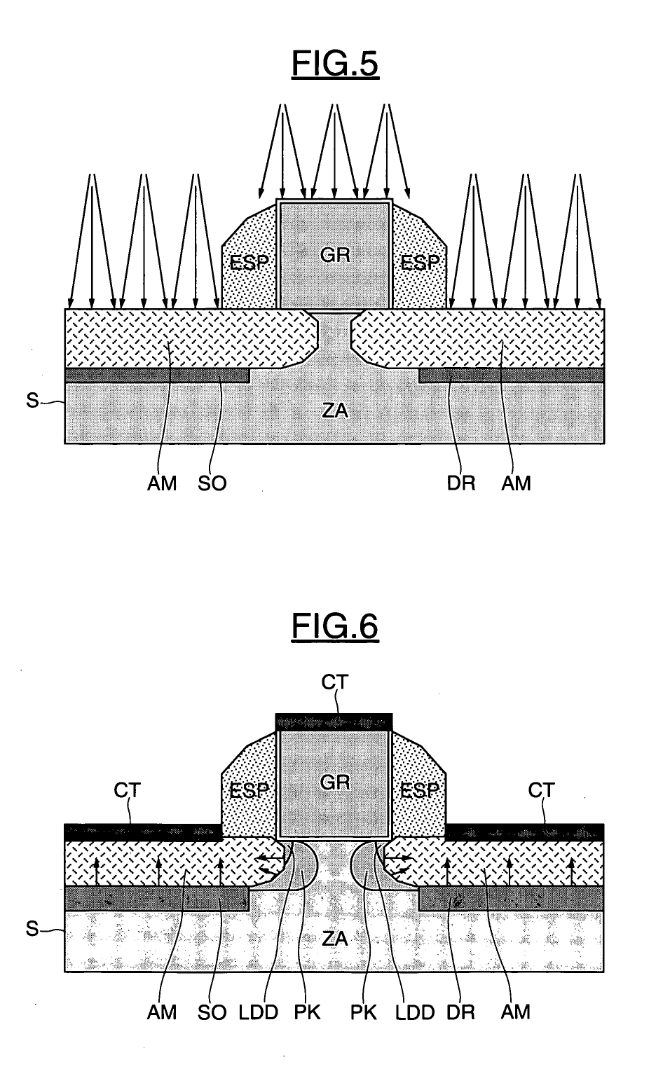

The next step is to amorphize a region AM sufficiently deep for it to extend laterally over a distance of greater than that of the spacer ESP, as illustrated in FIG. 5. The characteristics of the amorphous zone, especially its surface, are controlled by the choice of amorphization conditions, especially by the implantation of electrically neutral heavy ions with a chosen dose, with a chosen energy and at a chosen angle. Advantageously, the heavy ions are chosen from silicon, germanium, argon, neon, zenon and krypton.

For example, the implantation of Ge⁺ions with an energy of 60 keV at 0° with a dose of 10¹⁵ ions per cm² makes it possible to amorphize the substrate to a depth of 80 nm. By adding to this the implantation of Ge⁺ions with an energy of 60 keV at an angle of incidence of 30° with a dose of 10¹⁵ ions per cm² and the implantation of Ge⁺ions with an energy of 70 keV at an angle of incidence of 350 with a dose of 10¹⁵ ions per cm², the region AM completely covers the previously implanted extension LDD. The region AM extends over a thickness of greater than 100 nanometers.

The upper surface of the substrate and of the gate are silicided to form contacts CT made of TiSi₂ or CoSi₂ for example, as illustrated in FIG. 6. Siliciding requires a thermal budget that may be sufficient to recrystallize the zone AM and activate all of the dopants present in the substrate. The silicide is usually formed between 400 and 800° C. A temperature of around 700° C. sufficient to recrystallize the zone AM and activate the dopants.

In one variation as illustrated in FIG. 7, a recrystallization annealing step, separate from the siliciding, may be carried out beforehand. The annealing will be at a temperature below 800° C. The siliciding temperature will be below 600° C. to prevent diffusion of the dopants by exceeding the thermal budget.

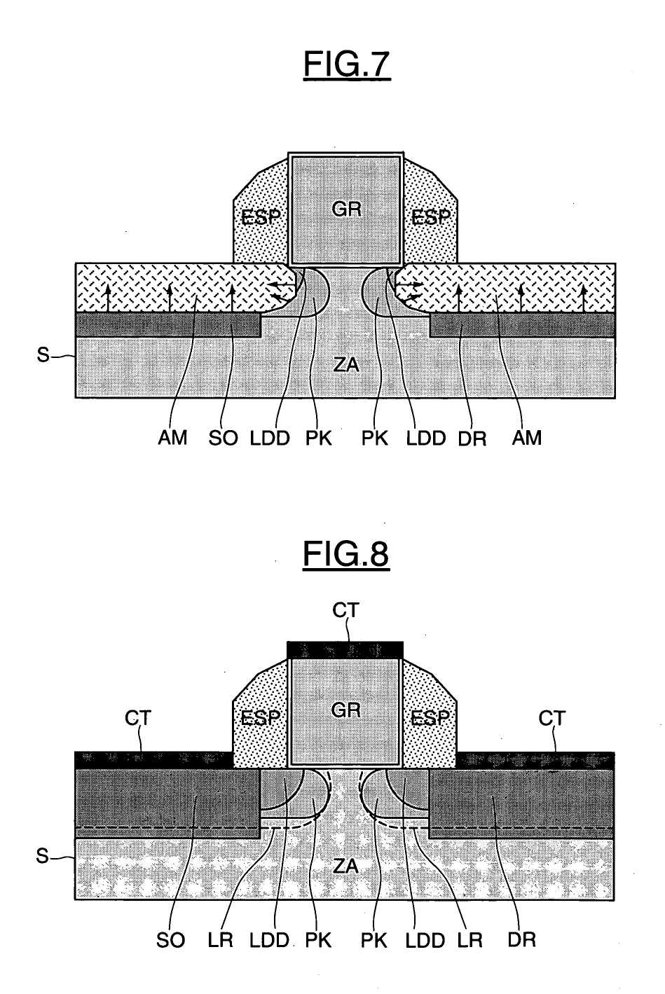

A high-performance transistor (illustrated in FIG. 8) is thus obtained in which the residual lines LR of crystal defects lie outside the extensions LDD, resulting in a very low leakage and in reduced short-channel effects.

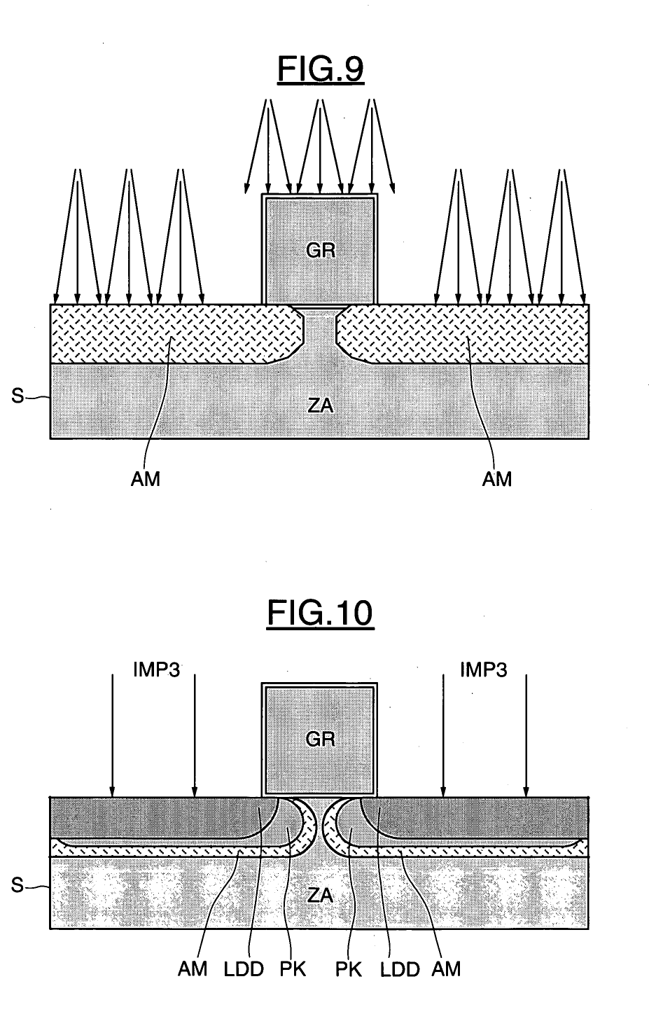

In one variation, the source SO and drain DR regions are implanted after amorphization of the region AM. In another variation as illustrated in FIGS. 9 and 10, the amorphization of the region AM is carried out first (FIG. 9), followed by the implantation IMP3 of dopants to form the extensions LDD, and optionally, the implantation of dopants to form the pockets PK (FIG. 10). Then the following are carried out: low-temperature formation of spacers, the amorphization of the source and drain regions and the implantation of dopants form the source SO and drain DR regions. Optionally, a recrystallization annealing step is then carried out as illustrated in FIG. 7. Next, the siliciding step is carried out as illustrated in FIG. 6.

By virtue of the invention, a transistor is fabricated with a gate length of less than 100 nm and with an ultrashort, ultrathin and a low-resistance LDD junction. The small thickness minimizes the short-channel effects and the DIBL effect. The fabrication is inexpensive since annealing steps may be carried out that take advantage of the thermal budget of other steps, especially the spacer formation step or the siliciding step.

Moreover, the spacers adjacent to the gate may be permanently formed and maintained. The invention also utilizes existing fabrication steps resulting in a process that is rapid and straightforward to implement. The invention applies to n-channel or p-channel MOS transistors, and more generally, to field-effect transistors and to bipolar transistors. The source SO and drain DR regions and the extensions LDD may benefit from the same dopant activation and silicon recrystallization steps.

That which is claimed is:

1. Process for fabricating an integrated circuit, comprising a substrate of crystalline silicon and a gate formed on the substrate, in which:
a single step of amorphizing a region of the substrate is carried out in order to obtain an amorphous silicon region;
a step of implanting a dopant species in a subregion lying substantially within the said region of the substrate is carried out in order to form drain and source extensions; and
a step of forming the source and drain at low temperature is carried out.

2. Process according to claim 1, in which, after the implantation step, a spacer formation step is carried out.

3. Process according to claim 1 or 2, in which, after the implantation step, a low-temperature annealing step is carried out.

4. Process according to any one of the preceding claims, in which the source and drain formation step includes a deep amorphization substep.

5. Process according to any one of the preceding claims, in which the source and drain formation step includes a dopant species implantation substep.

6. Process according to claim 4 or 5, in which, after the deep amorphization step or the dopant species implantation step, a silicon recrystallization substep is carried out.

7. Process according to claim 2, in which the step of forming the spacers includes a low-temperature annealing substep.

8. Process according to claim 2, in which an annealing step is carried out after formation of the spacers.

9. Process according to any one of the preceding claims, in which a step of forming pockets in the substrate is carried out, said pockets being doped with a dopant species having the opposite conductivity to that of the dopant species of the implantation step.

10. Process according to claim 9, in which the step of forming the doped pockets takes place before the amorphization step.

11. Process according to claim 9, in which the step of forming the doped pockets takes place after the amorphization step.

12. Process according to claim 9 or 10, in which the step of forming the doped pockets takes place before the amorphization step and before the dopant species implantation step.

13. Process according to any one of the preceding claims, in which a step of forming the spacers is carried out after the dopant species implantation step.

14. Process according to any one of the preceding claims, in which a step of forming the spacers is carried out before the amorphization step.

15. Process according to any one of the preceding claims, in which the amorphization step takes place to a thickness of greater than 100 nanometers.

16. Process according to any one of the preceding claims, in which a source and drain implantation step is carried out after the amorphization step.

17. Process according to any one of the preceding claims, in which the source and drain formation step includes a low-temperature annealing step.

18. Process according to any one of the preceding claims, in which the amorphization step includes the implantation of electrically inactive heavy ions.

19. Process according to claim 18, in which the heavy ions are chosen from silicon, germanium, argon, neon, zenon and krypton.

20. Process according to any one of the preceding claims, in which the dopant species implanted during the said implantation step is chosen from the following species: B⁺, BF₂⁺, In⁺, As⁺, P⁺ and Sb⁺.

21. Process according to any one of the preceding claims, in which the temperature of the source and drain formation step is below 800° C.

22. Integrated circuit comprising at least one transistor obtained by the process according to one of claims 1 to 21.

23. Integrated circuit according to claim 22, characterized in that the gate length of the transistor, measured parallel to the length of the channel, is less than 180 nanometers.

24. Integrated circuit according to claim 23, characterized in that the gate length of the transistor, measured parallel to the length of the channel, is less than 100 nanometers.
